(19) United States
(12) Patent Application Publication
(10) Pub. No.: US 2025/0182804 A1
(43) Pub. Date: Jun. 5, 2025

(54) MAGNETIC ARRAY, CONTROL METHOD FOR MAGNETIC ARRAY, AND OPERATION PROGRAM FOR MAGNETIC ARRAY

(71) Applicant: TDK CORPORATION, Tokyo (JP)

(72) Inventor: Shogo YAMADA, Tokyo (JP)

(73) Assignee: TDK CORPORATION, Tokyo (JP)

(21) Appl. No.: 18/844,170

(22) PCT Filed: Mar. 9, 2022
(86) PCT No.: PCT/JP2022/010284

§ 371 Date: Sep. 5, 2024

(51) Int. Cl. G11C 11/16; H10B 61/00

(52) U.S. Cl. CPC G11C 11/1675; G11C 11/161; H10B 61/20

(57) ABSTRACT

A magnetic array includes a plurality of magnetoresistance effect elements and a pulse application device configured to apply a pulse to at least one of the plurality of magnetoresistance effect elements. Each of the plurality of magnetoresistance effect elements includes a magnetic domain wall movement layer, a ferromagnetic layer, and a nonmagnetic layer interposed between the magnetic domain wall movement layer and the ferromagnetic layer. The pulse application device outputs a first pulse and a second pulse at different times. Voltages of both the first pulse and the second pulse are voltages at which a current density equal to or higher than a threshold current density required for moving a magnetic domain wall of the magnetic domain wall movement layer is acquired. The second pulse has a higher voltage than the first pulse or a longer pulse length than the first pulse. The pulse application device outputs the second pulse whenever the first pulse is output at a prescribed frequency or with a prescribed probability.

### TECHNICAL FIELD

The present invention relates to a magnetic array, a control method for a magnetic array, and an operation program for a magnetic array.

### BACKGROUND ART

A magnetoresistance effect element using a resistance change (a magnetoresistance change) based on a change of a relative angle of magnetization between two ferromagnetic layers is known. For example, a magnetic domain wall movement type magnetoresistance effect element (hereinafter referred to as a magnetic domain wall movement element) described in Patent Document 1 is an example of such a magnetoresistance effect element. A magnetic domain wall movement element changes in resistance in a stacking direction according to a position of a magnetic domain wall and can record multi-values or analog data.

A magnetic domain wall movement element can be used, for example, as a neuromorphic device that imitates a function of the brain as described in Patent Document 2.

### CITATION LIST

### Patent Document

Patent Document 1
Japanese Patent No. 5441005
Patent Document 2
Japanese Unexamined Patent Application, First Publication No. 2020-053660

### SUMMARY OF INVENTION

### Technical Problem

A magnetic domain wall movement element is often used for a magnetic array in which a plurality of elements are integrated. In each magnetic domain wall movement element, a trap site of a magnetic domain wall may be formed. A trap site traps a magnetic wall and hinders movement of the magnetic wall. For example, unevenness or the like formed in a magnetic domain wall movement layer may serve as a trap site. The position of a trap site formed in each magnetic domain wall movement element may be random due to manufacturing unevenness or the like. When a magnetic domain wall is trapped, an operation of the magnetic array becomes unstable. On the other hand, it is difficult to identify in what element a magnetic domain wall is trapped unless resistance values of the magnetic domain wall movement elements included in the magnetic array are individually detected.

The present invention was made in consideration of the aforementioned circumstances, and an objective thereof is to provide a magnetic array that can simply and stably operate. Another objective is to provide a control method for a magnetic array and an operation program for a magnetic array that can enable the magnetic array to operate stably.

### Solution to Problem

According to a first aspect, there is provided a magnetic array including a plurality of magnetoresistance effect elements and a pulse application device configured to apply a pulse to at least one of the plurality of magnetoresistance effect elements. Each of the plurality of magnetoresistance effect elements includes a magnetic domain wall movement layer, a ferromagnetic layer, and a nonmagnetic layer interposed between the magnetic domain wall movement layer and the ferromagnetic layer. The pulse application device outputs a first pulse and a second pulse at different times. Voltages of both the first pulse and the second pulse are voltages at which a current density equal to or higher than a threshold current density required for moving a magnetic domain wall of the magnetic domain wall movement layer is acquired. The second pulse has a higher voltage than the first pulse or a longer pulse length than the first pulse. The pulse application device outputs the second pulse whenever the first pulse is output at a prescribed frequency or with a prescribed probability.

According to a second aspect, there is provided a magnetic array including a plurality of magnetoresistance effect elements and a pulse application device configured to apply a pulse to at least one of the plurality of magnetoresistance effect elements. Each of the plurality of magnetoresistance effect elements includes a magnetic domain wall movement layer, a ferromagnetic layer, and a nonmagnetic layer interposed between the magnetic domain wall movement layer and the ferromagnetic layer. The pulse application device outputs a first pulse at a constant pulse interval and then outputs a second pulse at a pulse interval shorter than the constant pulse interval. The pulse application device outputs the second pulse whenever the first pulse is output at a prescribed frequency or with a prescribed probability. Voltages of both the first pulse and the second pulse are voltages at which a current density equal to or higher than a threshold current density required for moving a magnetic domain wall of the magnetic domain wall movement layer is acquired.

According to a third aspect, there is provided a magnetic array including a plurality of magnetoresistance effect elements and a pulse application device configured to apply a pulse to at least one of the plurality of magnetoresistance effect elements. Each of the plurality of magnetoresistance effect elements includes a magnetic domain wall movement layer, a ferromagnetic layer, and a nonmagnetic layer interposed between the magnetic domain wall movement layer and the ferromagnetic layer. The pulse application device outputs a learning pulse and a trap-escape pulse at different times. Voltages of both the learning pulse and the trap-escape pulse are voltages at which a current density equal to or higher than a threshold current density required for moving a magnetic domain wall of the magnetic domain wall movement layer is acquired. The voltage of the trap-escape pulse is larger than the voltage of the learning pulse or a pulse length of the trap-escape pulse is larger than the pulse length of the learning pulse.

According to a fourth aspect, there is provided an operation method for a magnetic array, including: a step of applying a first pulse to a plurality of magnetoresistance effect elements; and a step of applying a second pulse to the plurality of magnetoresistance effect elements whenever the first pulse is applied at a prescribed frequency or with a prescribed probability. Each of the plurality of magnetoresistance effect elements includes a magnetic domain wall movement layer, a ferromagnetic layer, and a nonmagnetic layer interposed between the magnetic domain wall movement layer and the ferromagnetic layer. Voltages of both the first pulse and the second pulse are voltages at which a current density equal to or higher than a threshold current density required for moving a magnetic domain wall of the magnetic domain wall movement layer is acquired. The second pulse has a higher voltage than the first pulse or a longer pulse length than the first pulse.

According to a fifth aspect, there is provided an operation method for a magnetic array, including: a step of applying a first pulse to a plurality of magnetoresistance effect elements; and a step of applying a second pulse to the plurality of magnetoresistance effect elements whenever the first pulse is applied at a prescribed frequency or with a prescribed probability. Each of the plurality of magnetoresistance effect elements includes a magnetic domain wall movement layer, a ferromagnetic layer, and a nonmagnetic layer interposed between the magnetic domain wall movement layer and the ferromagnetic layer. The first pulse is applied at a constant pulse interval, and the second pulse is applied at a pulse interval shorter than the constant pulse interval. Voltages of both the first pulse and the second pulse are voltages at which a current density equal to or higher than a threshold current density required for moving a magnetic domain wall of the magnetic domain wall movement layer is acquired.

According to a sixth aspect, there is provided an operation program for a magnetic array causing a computer to perform: a first process of applying a first pulse to a plurality of magnetoresistance effect elements; and a second process of applying a second pulse to the plurality of magnetoresistance effect elements whenever the first pulse is applied at a prescribed frequency or with a prescribed probability. Each of the plurality of magnetoresistance effect elements includes a magnetic domain wall movement layer, a ferromagnetic layer, and a nonmagnetic layer interposed between the magnetic domain wall movement layer and the ferromagnetic layer. Voltages of both the first pulse and the second pulse are voltages at which a current density equal to or higher than a threshold current density required for moving a magnetic domain wall of the magnetic domain wall movement layer is acquired. The second pulse has a higher voltage than the first pulse or a longer pulse length than the first pulse.

According to a seventh aspect, there is provided an operation program for a magnetic array causing a computer to perform: a first process of applying a first pulse to a plurality of magnetoresistance effect elements; and a second process of applying a second pulse to the plurality of magnetoresistance effect elements whenever the first pulse is applied at a prescribed frequency or with a prescribed probability. Each of the plurality of magnetoresistance effect elements includes a magnetic domain wall movement layer, a ferromagnetic layer, and a nonmagnetic layer interposed between the magnetic domain wall movement layer and the ferromagnetic layer. The operation program is instructed to apply the first pulse at a constant pulse interval and to apply the second pulse at a pulse interval shorter than the constant pulse interval. Voltages of both the first pulse and the second pulse are voltages at which a current density equal to or higher than a threshold current density required for moving a magnetic domain wall of the magnetic domain wall movement layer is acquired.

### Advantageous Effects of Invention

With the magnetic array, the control method for a magnetic array, and the operation program for a magnetic array according to the aspects, it is possible to simply stabilize an operation of the magnetic array.

### BRIEF DESCRIPTION OF DRAWINGS

FIG. 1 is a block diagram illustrating a magnetic array according to a first embodiment.

FIG. 2 is a circuit diagram illustrating an integrated area of the magnetic array according to the first embodiment.

FIG. 3 is a sectional view of the vicinity of a magnetic domain wall movement element of the magnetic array according to the first embodiment.

FIG. 4 is a sectional view of a first example of a magnetic domain wall movement element according to the first embodiment.

FIG. 5 is a plan view of the first example of the magnetic domain wall movement element according to the first embodiment.

FIG. 6 is a sectional view of a second example of the magnetic domain wall movement element according to the first embodiment.

FIG. 7 is a flowchart illustrating an example of an operation program according to the first embodiment.

FIG. 8 is a diagram illustrating an example of temporal change of a pulse which is output by a pulse application device of the magnetic array according to the first embodiment.

FIG. 9 is a diagram illustrating another example of temporal change of a pulse which is output by the pulse application device of the magnetic array according to the first embodiment.

FIG. 10 is a diagram illustrating another example of temporal change of a pulse which is output by the pulse application device of the magnetic array according to the first embodiment.

FIG. 11 is a diagram illustrating another example of temporal change of a pulse which is output by the pulse application device of the magnetic array according to the first embodiment.

FIG. 12 is a flowchart illustrating another example of the operation program according to the first embodiment.

FIG. 13 is a diagram illustrating another example of temporal change of a pulse which is output by the pulse application device of the magnetic array according to the first embodiment.

FIG. 14 is a diagram illustrating another example of temporal change of a pulse which is output by the pulse application device of the magnetic array according to the first embodiment.

FIG. 15 is a diagram schematically illustrating a neural network.

### DESCRIPTION OF EMBODIMENTS

Hereinafter, embodiments will be described in detail with reference to the accompanying drawings. In the drawings referred to in the following description, featured constituents may be conveniently enlarged, and dimensions, proportions, and the like of the constituents may be different from actual ones. Materials, dimensions, and the like provided as exemplary examples in the following description are only examples, and the present invention is not limited thereto and can be appropriately modified within a range in which the advantages of the present invention are achieved.

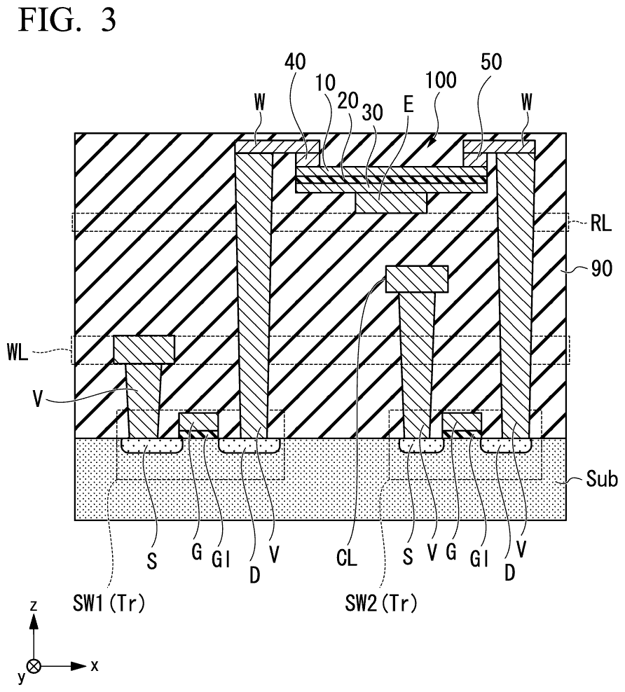

Directions will be defined as follows. An x direction and a y direction are directions substantially parallel to one surface of a substrate Sub (see FIG. 3) which will be described later. The x direction is a direction in which a magnetic domain wall movement layer 10 which will be described later extends. The y direction is a direction perpendicular to the x direction. A z direction is a direction directed from the substrate Sub which will be described later to a magnetic domain wall movement element 100. In this specification, the +z direction may be mentioned as “upward” and the −z direction may be mentioned as “downward,” which are for convenience and does not define a gravitational force direction. In this specification, “extending in the x direction” means, for example, that a dimension in the x direction is larger than a minimum value of dimensions in the x direction, the y direction, and the z direction. The same is true of extending in the other directions. In this specification, “connect” is not limited to a direct connection and includes a case in which another object is interposed.

### First Embodiment

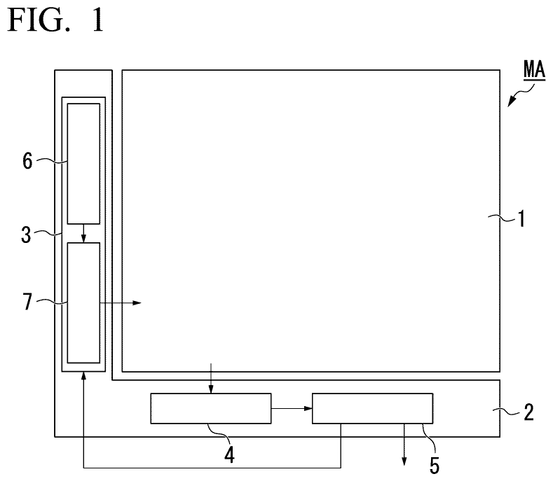

FIG. 1 is a block diagram illustrating a magnetic array MA according to a first embodiment. The magnetic array MA includes an integrated area 1 and a peripheral area 2. The magnetic array MA can be used, for example, in a magnetic memory, a product-sum operator, a neuromorphic device, a spin memristor, or a magneto-optical device.

The integrated area 1 is an area in which a plurality of magnetic domain wall movement elements are integrated. A magnetic domain wall movement element is an example of a magnetoresistance effect element. When the magnetic array MA is used as a memory, data is accumulated in the integrated area 1. When the magnetic array MA is used as a neuromorphic device, learning is performed in the integrated area 1.

The peripheral area 2 is an area in which a control element for controlling operations of the magnetic domain wall movement elements in the integrated area 1. The peripheral area 2 includes, for example, a pulse application device 3, a resistance detection device 4, and an output unit 5.

The pulse application device 3 is configured to apply a pulse to at least one of the plurality of magnetic domain wall movement elements in the integrated area 1. The pulse application device 3 includes, for example, a control unit 6 and a power supply 7.

The control unit 6 includes, for example, a processor and a memory. The processor is, for example, a central processing unit (CPU). The processor operates on the basis of an operation program stored in the memory. Details of the operation program will be described later. The control unit 6 controls an address of a magnetic domain wall movement element to which a pulse is to be applied, magnitudes (a voltage and a pulse length) of a pulse to be applied to a predetermined magnetic domain wall movement element, and the like. The control unit 6 may further include a clock, a counter, and a random number generator. The clock serves as an index of a timing at which a pulse is applied, and the counter counts the number of times of pulse application or the like. The power supply 7 applies a pulse to a magnetic domain wall movement element in accordance with an instruction from the control unit 6.

The resistance detection device 4 is configured to detect resistance values of the magnetic domain wall movement elements in the integrated area 1. The resistance detection device 4 may detect a resistance of each magnetic domain wall movement element in the integrated area 1 or may detect a sum of resistance values of the magnetic domain wall movement elements belonging to the same column. The resistance detection device 4 includes, for example, a comparator for comparing the magnitudes of the detected resistance values. The comparator may compare, for example, the detected resistance values or may compare the detected resistance values with a preset reference resistance value.

The output unit 5 is connected to the resistance detection device 4. The output unit 5 includes, for example, a processor, an output capacitor, an amplifier, and a converter. When the magnetic array MA is used as a neuromorphic device, the output unit 5 may perform an arithmetic operation of substituting a detection result from the resistance detection device 4 into an activation function. The arithmetic operation is performed, for example, by the processor. The output unit 5 externally outputs an operation result. When the magnetic array MA is used as a neuromorphic device, the output unit 5 may perform an operation of outputting the operation result as an input signal of another magnetic array or the like or may perform an operation of externally outputting the operation result as an accuracy ratio or the like. The output unit 5 may feed the operation result back to the pulse application device 3.

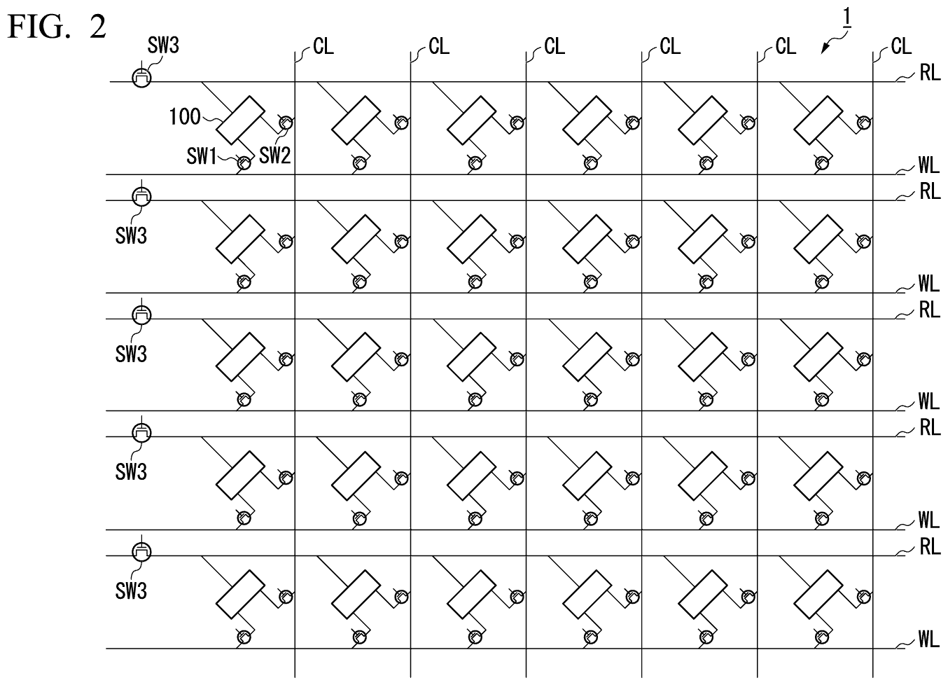

FIG. 2 is a circuit diagram of the integrated area 1 according to the first embodiment. The integrated area 1 includes a plurality of magnetic domain wall movement elements 100, a plurality of first line WL, a plurality of second lines CL, a plurality of third lines RL, a plurality of first switching elements SW1, and a plurality of second switching elements SW2. A third switching element SW3 may be included, for example, in the pulse application device 3 of the peripheral area 2.

The plurality of magnetic domain wall movement elements 100 are arranged, for example, in a matrix shape. The plurality of magnetic domain wall movement elements 100 are not limited to arrangement of actual elements in a matrix shape and may be arranged in a matrix in a circuit diagram.

Each first line WL is a wiring line. The first line WL electrically connects the pulse application device 3 to one or more magnetic domain wall movement elements 100. Each second line CL is a common line which can be used for both writing and reading of data. Each second line CL is connected to, for example, the resistance detection device 4. The second line CL may be provided in each of the plurality of magnetic domain wall movement elements 100 or may be provided over a plurality of magnetic domain wall movement elements 100. Each third line RL is a reading line. Each third line RL electrically connects the pulse application device 3 to one or more magnetic domain wall movement elements 100.

The first switching element SW1, the second switching element SW2, and the third switching element SW3 are elements for controlling a flow of a current. The first switching element SW1, the second switching element SW2, and the third switching element SW3 are, for example, transistors, elements using a phase shift of a crystal layer such as ovonic threshold switches (OTSs), elements using a change in band structure such as metal-insulator transition (MIT) switches, elements using a breakdown voltage such as Zener diodes and avalanche diodes, and elements of which conductivity changes with a change in atom position.

The first switching element SW1 and the second switching element SW2 are connected to, for example, each magnetic domain wall movement element 100. The first switching element SW1 is connected, for example, between the magnetic domain wall movement element 100 and the corresponding first line WL. The second switching element SW2 is connected, for example, between the magnetic domain wall movement element 100 and the corresponding second line CL. The third switching element SW3 is connected to, for example, a plurality of magnetic domain wall movement elements 100. The third switching element SW3 is connected to, for example, the corresponding third line RL.

The positional relationship among the first switching elements SW1, the second switching elements SW2, and the third switching elements SW3 is not limited to the example illustrated in FIG. 2. For example, the first switching element SW1 may be connected to a plurality of magnetic domain wall movement elements 100 and located upstream from the first line WL. For example, the second switching element SW2 may be connected to a plurality of magnetic domain wall movement elements 100 and located upstream from the second line CL. For example, the third switching element SW3 may be connected to each magnetic domain wall movement element 100.

FIG. 3 is a sectional view of the vicinity of a magnetic domain wall movement element 100 of the magnetic array MA according to the first embodiment. FIG. 3 illustrates a sectional view of one magnetic domain wall movement element 100 in FIG. 2 taken with an xz plane passing through the center in the y direction of the magnetic domain wall movement layer 10.

The first switching element SW1 and the second switching element SW2 illustrated in FIG. 3 are transistors Tr. Each transistor Tr includes a gate electrode G, a gate insulating film GI, and a source S and a drain D formed in the substrate Sub. The source S and the drain D are determined according to a flow direction of a current and are the same region. FIG. 3 illustrates only an example, and the positional relationship between the source S and the drain D may be inverted. The substrate Sub is, for example, a semiconductor substrate. The third switching element SW3 is electrically connected to the third line RL and is located, for example, at a position shifted in the x direction in FIG. 3.

The transistors Tr, the first line WL, the second line CL, the third line RL, and the magnetic domain wall movement element 100 which are located in different layers in the z direction are connected to each other via a via-wiring V extending in the z direction or a wiring W extending in one direction of the xy plane. The via-wiring V and the wiring W include a conductive material. An insulating layer 90 is formed between the different layers in the z direction except the via-wiring V.

The insulating layer 90 is an insulating layer insulating multi-layered lines or elements from each other. The magnetic domain wall movement element 100 and the transistors Tr are electrically isolated by the insulating layer 90 except the via-wiring V. The insulating layer 90 is formed of, for example, silicon oxide (SiOₓ), silicon nitride (SiNₓ), silicon carbide (SiC), chromium nitrid, silicon carbide nitride (SiCN), silicon nitride oxide (SiON), aluminum oxide (Al₂O₃), or zirconium oxide (ZrOₓ).

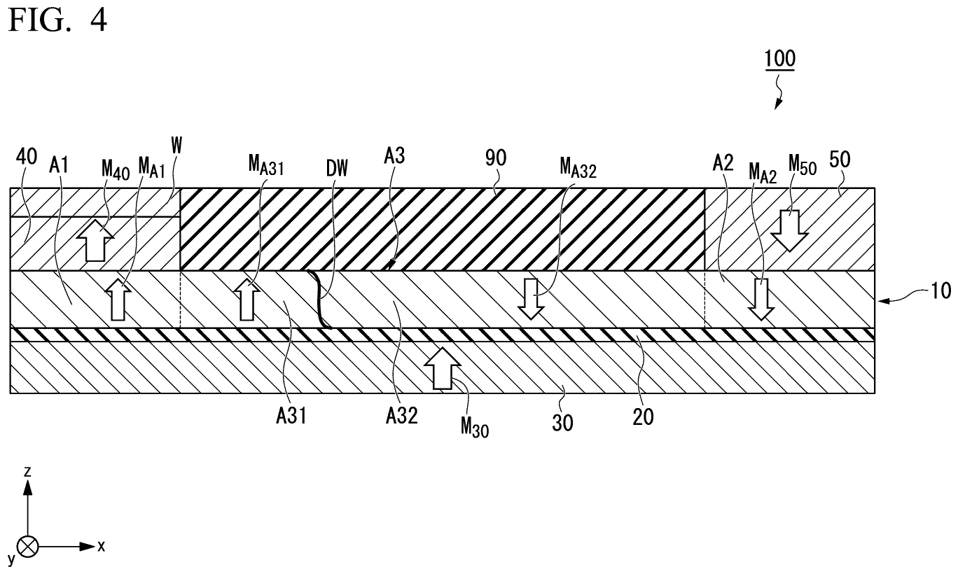

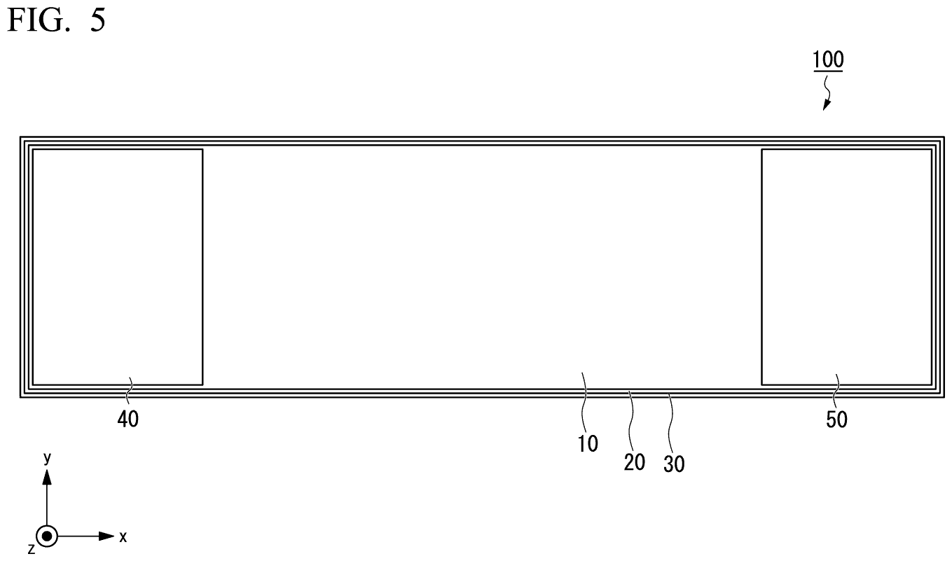

FIG. 4 is a sectional view of the vicinity of a magnetic domain wall movement element 100 taken with the xz plane passing through the center in the y direction of the magnetic domain wall movement layer 10. Arrows in the drawing are examples of magnetization orientation directions of a ferromagnetic material. FIG. 5 is a plan view of the magnetic domain wall movement element 100 when seen in the z direction.

The magnetic domain wall movement element 100 includes, for example, a magnetic domain wall movement layer 10, a nonmagnetic layer 20, a ferromagnetic layer 30, a first magnetization fixing layer 40, and a second magnetization fixing layer 50.

The magnetic domain wall movement layer 10 extends in the x direction. The magnetic domain wall movement layer 10 includes a plurality of magnetic domains therein and includes a magnetic domain wall DW at a boundary between the plurality of magnetic domains. The magnetic domain wall movement layer 10 is, for example, a layer that can magnetically record information using a change in magnetic status. The magnetic domain wall movement layer 10 is also referred to as an analog layer or a magnetic recording layer.

The magnetic domain wall movement layer 10 includes a first area A1, a second area A2, and a third area A3. The first area A1 is an area overlapping the first magnetization fixing layer 40 when seen in the z direction. The second area A2 is an area overlapping the second magnetization fixing layer 50 when seen in the z direction. The third area A3 is an area of the magnetic domain wall movement layer 10 other than the first area A1 and the second area A2. The third area A3 is an area interposed between the first area A1 and the second area A2 in the x direction.

Magnetization M_{A1} of the first area A1 is fixed by magnetization M₄₀ of the first magnetization fixing layer 40. Magnetization M_{A2} of the second area A2 is fixed by magnetization M₅₀ of the second magnetization fixing layer 50. Fixation of magnetization means that magnetization is not inverted in a normal operation (in which a larger external force than conceivable is not applied thereto) of the magnetic domain wall movement element 100. The first area A1 and the second area A2 have, for example, magnetization orientation directions which are opposite.

The third area A3 is an area in which a magnetization direction changes and the magnetic domain wall DW is movable. The third area A3 is referred to as a magnetic domain wall movable area. The third area A3 includes a first magnetic domain A31 and a second magnetic domain A32. The first magnetic domain A31 and the second magnetic domain A32 have magnetization orientation directions which are opposite. A boundary between the first magnetic domain A31 and the second magnetic domain A32 is the magnetic domain wall DW. Magnetization M_{A31} of the first magnetic domain A31 is orientated, for example, in the same direction as the magnetization M_{A1} of the first area A1. Magnetization M_{A32} of the second magnetic domain A32 is orientated, for example, in the same direction as the magnetization M_{A2} of the second area A2. In principles, the magnetic domain wall DW moves in the third area A3 and does not invade into the first area A1 and the second area A2.

When a volume ratio of the first magnetic domain A31 and the second magnetic domain A32 in the third area A3 changes, the magnetic domain wall DW moves. The magnetic domain wall DW moves by causing a writing current to flow in the x direction of the third area A3, applying an external magnetic field to the third area A3, or the like. For example, when a writing current (for example, a current pulse) in the +x direction is applied to the third area A3, electrons flow in the −x direction which is opposite to that of the current and thus the magnetic domain wall DW moves in the −x direction. When a current flows from the first magnetic domain A31 to the second magnetic domain A32, electrons spin-polarized by the second magnetic domain A32 inverts the magnetization M_{A31} of the first magnetic domain A31. When the magnetization M_{A31} of the first magnetic domain A31 is inverted, the magnetic domain wall DW moves in the −x direction.

The magnetic domain wall movement layer 10 is formed of a magnetic substance. The magnetic domain wall movement layer 10 may be a ferromagnetic substance, a ferrimagnetic substance, or a combination of an antiferromagnetic substance capable of changing a magnetic state using a current therewith. It is preferable that the magnetic domain wall movement layer 10 include at least one element selected from a group consisting of Co, Ni, Fe, Pt, Pd, Gd, Tb, Mn, Ge, and Ga. Examples of a material used for the magnetic domain wall movement layer 10 include a stacked film of Co and Ni, a stacked film of Co and Pt, a stacked film of Co and Pd, a MnGa-based material, a GdCo-based material, and a TbCo-based material. With a ferrimagnetic substance such as a MnGa-based material, a GdCo-based material, and a TbCo-based material, a saturated magnetization is small and the threshold current required for moving the magnetic domain wall DW is small. With a stacked film of Co and Ni, a stacked film of Co and Pt, and a stacked film of Co and Pd, the coercivity is large and the moving speed of the magnetic domain wall DW is low. Examples of the antiferromagnetic substance include Mn₃X (where X is Sn, Ge, Ga, Pt, Ir, or the like), CuMnAs, and Mn₂Au. The same material as the ferromagnetic layer 30 which will be described later can also be used for the magnetic domain wall movement layer 10.

The nonmagnetic layer 20 is located between the magnetic domain wall movement layer 10 and the ferromagnetic layer 30. The nonmagnetic layer 20 is stacked on one surface of the ferromagnetic layer 30.

The nonmagnetic layer 20 is formed of, for example, a nonmagnetic insulating material, a semiconductor, or a metal. Examples of the nonmagnetic insulating material include Al₂O₃, SiO₂, MgO, MgAl₂O₄, and a material in which a part of Al, Si, or Mg thereof is replaced with Zn, Be, or the like. These materials have a large band gap and excellent insulation properties. When the nonmagnetic layer 20 is formed of a nonmagnetic insulating material, the nonmagnetic layer 20 is a tunnel barrier layer. Examples of the nonmagnetic metal include Cu, Au, and Ag. Examples of the nonmagnetic semiconductor include Si, Ge, CuInSe₂, CuGaSe₂, and Cu(In, Ga)Se₂.

The thickness of the nonmagnetic layer 20 is equal to or greater than, for example, 20 Å and may be equal to or greater than 25 Å. When the thickness of the nonmagnetic layer 20 increases, a resistance-area product (RA) of the magnetic domain wall movement element 100 increases. The resistance-area product (RA) of the magnetic domain wall movement element 100 is preferably equal to or greater than 1×10⁴ Ωμm² and more preferable equal to or greater than 5×10⁴ Ωμm². The resistance-area product (RA) of the magnetic domain wall movement element 100 is expressed as a product of element resistance of the magnetic domain wall movement element 100 and an element sectional area (an area of a section of the nonmagnetic layer 20 taken with an xy plane) of the magnetic domain wall movement element 100.

The ferromagnetic layer 30 interposes the nonmagnetic layer 20 along with the magnetic domain wall movement layer 10 therebetween. At least a part of the ferromagnetic layer 30 is located at a position overlapping the magnetic domain wall movement layer 10 in the z direction. The magnetization of the ferromagnetic layer 30 is less likely to be inverted than the magnetization of the third area A3 of the magnetic domain wall movement layer 10. The magnetization of the ferromagnetic layer 30 does not change in direction and is fixed when an external force that can invert the magnetization of the third area A3 is applied thereto. The ferromagnetic layer 30 may be referred to as a fixed layer or a reference layer.

The ferromagnetic layer 30 is formed of a ferromagnetic substance. The ferromagnetic layer 30 includes, for example, a material capable of easily providing a coherent tunneling effect between the magnetic domain wall movement layer 10 and the ferromagnetic layer 30. The ferromagnetic layer 30 includes, for example, a metal selected from a group consisting of Cr, Mn, Co, Fe, and Ni, an alloy including one or more of such metals, or an alloy including such metals and one or more elements of B, C, and N. Examples of the second ferromagnetic layer 30 include Co—Fe, Co—Fe—B, and Ni—Fe.

The ferromagnetic layer 30 may be formed of, for example, a Heusler alloy. The Heusler alloy is a half metal and has a high spin polarizability. The Heusler alloy is an intermetallic compound having the chemical composition of XYZ or X₂YZ, where X is a transition metal element or a noble metal element of the group of Co, Fe, Ni, or Cu in the periodic table, Y is a transition metal of the group of Mn, V, Cr, or Ti or the element of X, and Z is a typical element of Groups III to V. Examples of the Heusler alloy include Co₂FeSi, Co₂FeGe, Co₂FeGa, Co₂MnSi, Co₂Mn₁₋ₐFeₐAl_{b}Si_{1-b}, and Co₂FeGe_{1-c}Ga_{c}.

The first magnetization fixing layer 40 and the second magnetization fixing layer 50 are connected to the magnetic domain wall movement layer 10. The first magnetization fixing layer 40 and the second magnetization fixing layer 50 are separated in the x direction. The first magnetization fixing layer 40 fixes the magnetization of the first area A1. The second magnetization fixing layer 50 fixes the magnetization of the second area A2.

The first magnetization fixing layer 40 and the second magnetization fixing layer 50 are formed of, for example, a ferromagnetic substance. The first magnetization fixing layer 40 and the second magnetization fixing layer 50 can be formed of, for example, the same material as the magnetic domain wall movement layer 10 or the ferromagnetic layer 30. The first magnetization fixing layer 40 and the second magnetization fixing layer 50 are not limited to a ferromagnetic substance. When the first magnetization fixing layer 40 and the second magnetization fixing layer 50 are not a ferromagnetic substance, a current density of a current flowing in the magnetic domain wall movement layer 10 changes rapidly in an area overlapping the first magnetization fixing layer 40 or the second magnetization fixing layer 50, whereby movement of the magnetic domain wall DW is limited and the magnetization of the first area A1 and the magnetization of the second area A2 are fixed.

The magnetic domain wall movement element 100 may include a layer other than the magnetic domain wall movement layer 10, the nonmagnetic layer 20, and the ferromagnetic layer 30. For example, a magnetic layer may be provided on a surface of the ferromagnetic layer 30 opposite to the nonmagnetic layer 20 with a spacer layer interposed therebetween. The ferromagnetic layer 30, the spacer layer, and the magnetic layer constitute a synthetic ferromagnetic structure (an SAF structure). The synthetic ferromagnetic structure includes two magnetic layers with a nonmagnetic layer interposed therebetween. When the ferromagnetic layer 30 and the magnetic layer are coupled in an antiferromagnetic manner, a coercivity of the ferromagnetic layer 30 becomes larger than that in a case in which the magnetic layer is not provided. The magnetic layer may include, for example, a ferromagnetic substance and may include an antiferromagnetic substance such as IrMn or PtMn. The spacer layer includes, for example, at least one selected from a group consisting of Ru, Ir, and Rh.

The magnetization directions of the layers of the magnetic domain wall movement element 100 can be ascertained, for example, by measuring a magnetization curve. The magnetization curve can be measured, for example, using a magneto-optical Kerr effect (MOKE). Measurement using the MOKE is a measurement method that is performed using a magneto-optical effect (a magnetic Kerr effect) of causing rotation of the polarization direction in response to incidence of linear polarized light on a measuring object.

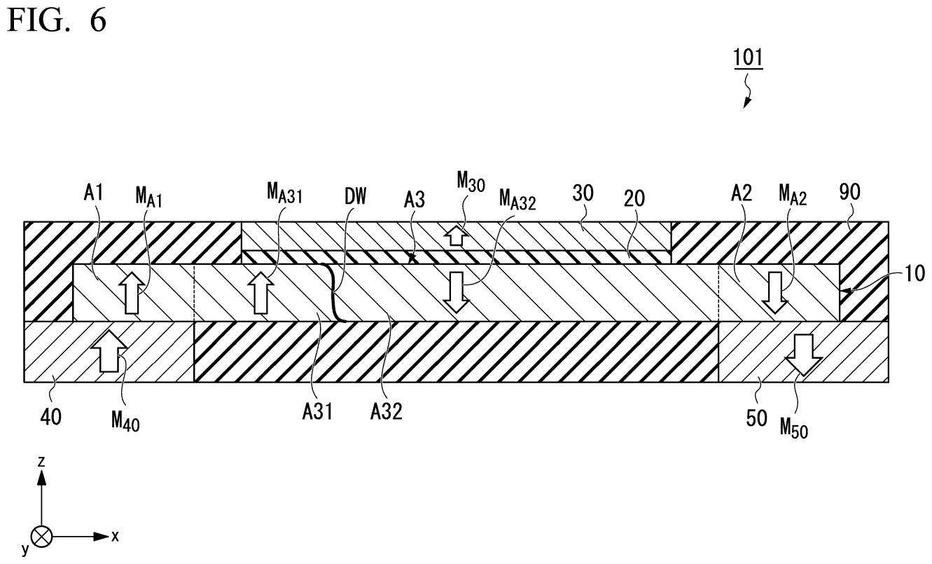

An example of a specific configuration of a magnetic domain wall movement element has been described above in conjunction with the magnetic domain wall movement element 100 illustrated in FIG. 4, but the structure of the magnetic domain wall movement element is not limited to this example. FIG. 6 is a sectional view of a magnetic domain wall movement element 101 according to a second example taken with the xz plane passing through the center in the y direction of the magnetic domain wall movement layer 10. The magnetic domain wall movement element 101 illustrated in FIG. 6 is different from the magnetic domain wall movement element 100 in that the ferromagnetic layer 30 is separated from the substrate Sub more than the magnetic domain wall movement layer 10. The magnetic domain wall movement element 101 is referred to as a top pin structure in which the ferromagnetic layer 30 which is a fixed layer is located at a position separated from the substrate Sub. The magnetic domain wall movement element 100 is referred to as a bottom pin structure in which the ferromagnetic layer 30 which is a fixed layer is located near the substrate Sub more than the magnetic domain wall movement layer 10. The magnetic domain wall movement element 100 can be replaced with the magnetic domain wall movement element 101.

The magnetic domain wall movement element 100 is formed using a stacking step of stacking layers and a processing step of processing some of the layers in a predetermined shape. Stacking of the layers can be performed using a sputtering method, a chemical vapor deposition (CVD) method, an electron beam deposition method (an EB deposition method), or an atomic laser deposition method. Processing of the layers can be performed using photolithography, etching (for example, Ar etching), and the like.

An operation of writing a signal to the magnetic array MA and an operation of reading a signal from the magnetic array MA will be described below.

First, the operation of writing a signal to the magnetic array MA will be described. The writing operation is performed, for example, by causing the processor to execute an operation program stored in the control unit 6.

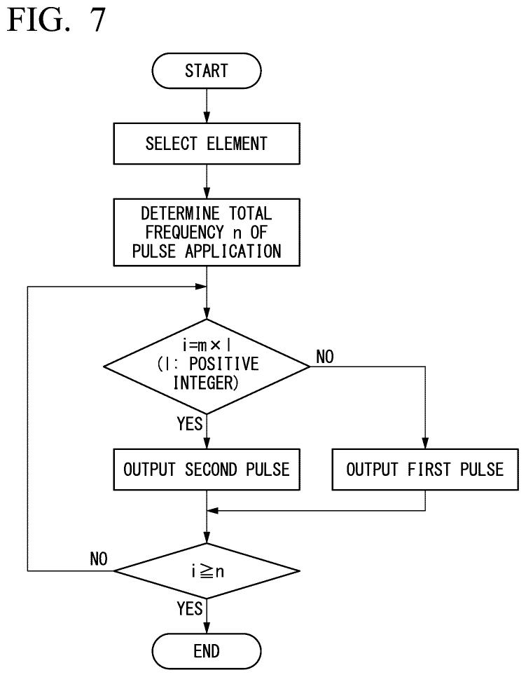

FIG. 7 is a flowchart illustrating an example of an operation program. The operation program includes a process of selecting a magnetic domain wall movement element 100 to which a pulse is to be applied, a process of determining a total frequency n in which a pulse is to be applied, a process of determining whether an application frequency i of a pulse is equal to a multiple of a prescribed frequency m, a process of applying a first pulse to a plurality of magnetic domain wall movement elements 100, a process of applying a second pulse to a plurality of magnetic domain wall movement elements 100, and a process of determining whether the application frequency i of a pulse is equal to or greater than the total frequency n.

First, the pulse application device 3 selects a magnetic domain wall movement element 100 to which a pulse is to be applied in accordance with an operation program. When the magnetic array MA is used as a magnetic memory, the magnetic domain wall movement element 100 to which a pulse is to be applied is an element storing data. When the magnetic array MA is used as a neural network, the magnetic domain wall movement element 100 to which a pulse is to be applied is an element performing learning.

To which magnetic domain wall movement element 100 out of a plurality of magnetic domain wall movement elements 100 a pulse is to be applied is controlled by the control unit 6. The control unit 6 turns on the first switching element SW1 and the second switching element SW2 connected to the magnetic domain wall movement element 100 to which a pulse is to be applied and turns off the first switching element SW1 and the second switching element SW2 connected to the other magnetic domain wall movement element 100.

Subsequently, the pulse application device 3 determines the total frequency n by which a pulse is to be applied in accordance with an operation program. The total frequency n by which a pulse is to be applied is determined, for example, for each magnetic domain wall movement element 100. The total number n by which a pulse is to be applied is, for example, a sum of the application frequency of the first pulse and the application frequency of the second pulse.

Subsequently, the pulse application device 3 outputs a pulse to a plurality of magnetic domain wall movement elements 100 in accordance with an operation program. The pulse is applied to the selected magnetic domain wall movement element 100. The pulse is applied across the first magnetization fixing layer 40 and the second magnetization fixing layer 50 along the magnetic domain wall movement layer 10 of the magnetic domain wall movement element 100.

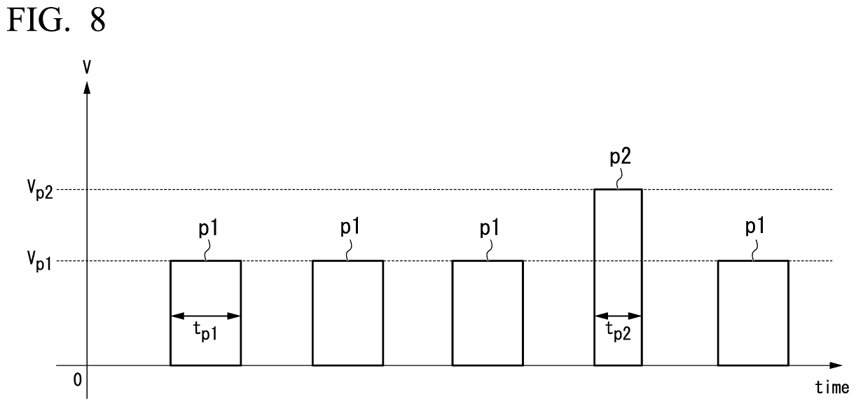

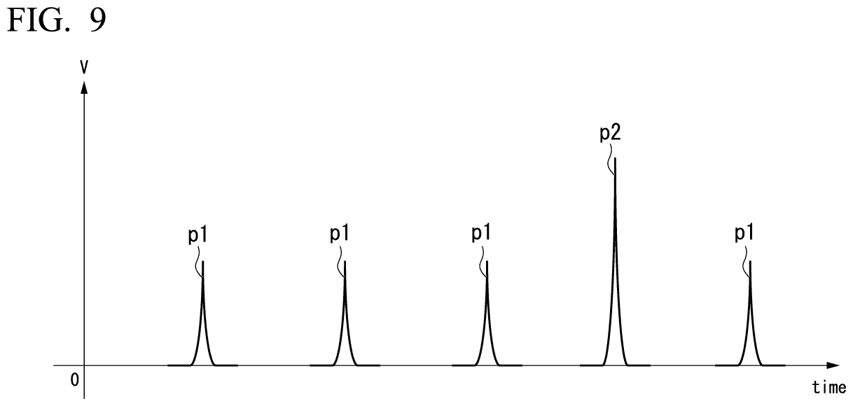

FIG. 8 illustrates a temporal change of a pulse which is output from the pulse application device 3. The pulse includes a first pulse p1 and a second pulse p2. In FIG. 8, the first pulse p1 and the second pulse p2 are positive pulses, but the first pulse p1 and the second pulse p2 may be negative pulses. References of a voltage and a time of a pulse can be arbitrarily set and are not limited to 0. The pulse application device 3 outputs the first pulse p1 and the second pulse p2 at different times. The first pulse p1 and the second pulse p2 may be rectangular waves as illustrated in FIG. 8, may be spike waves as illustrated in FIG. 9, or may have other waveforms.

Voltages Vₚ₁ and Vₚ₂ of both the first pulse p1 and the second pulse p2 are voltages with which a current density equal to or higher than a threshold current density required for moving the magnetic domain wall DW of the magnetic domain wall movement layer 10. That is, both the first pulse p1 and the second pulse p2 can move the magnetic domain wall DW. When the magnetic array MA is used as a magnetic memory, the first pulse p1 is a recording pulse for recording data. When the magnetic array MA is used as a neural network, the first pulse p1 is a learning pulse for learning.

The first pulse p1 is applied, for example, when the application frequency i of a pulse is not a multiple of the prescribed frequency m. The prescribed frequency m is set in advance. The prescribed frequency m corresponds to a frequency by which the first pulse is applied until the second pulse is applied. As the prescribed frequency m increases, the frequency by which the second pulse p2 is output decreases. The prescribed frequency m may be defined, for example, for each magnetic domain wall movement element 100, may be defined as the same frequency for all the magnetic domain wall movement elements 100, or may be defined for each row or column. For example, the prescribed frequency m may be defined for the magnetic domain wall movement elements 100 connected to the same first line WL.

The prescribed frequency m may change with the elapse of time. For example, when the magnetic array MA is used as a neural network, the prescribed frequency m may change according to a progress status of learning of the neural network. For example, when the magnetic array MA is used as a neural network, the prescribed frequency m is set to be higher at the time of end of learning than at the time of start of learning of the neural network. That is, the frequency by which the second pulse p2 is output is set to be lower at the time of end of learning than at the time of start of learning of the neural network.

The process status of learning is determined, for example, on the basis of an accuracy ratio which is output as an arithmetic operation result from the output unit 5. For example, as accuracy ratio increases, the prescribed frequency m increases. This is because, as the accuracy ratio increases, a movement range of the magnetic domain wall DW is narrowed and a probability with which the magnetic domain wall DW will be trapped decreases.

The operation program performs a process of determining whether the application frequency i of a pulse is equal to or greater than the total frequency n and a process of determining whether the application frequency i of a pulse is equal to a multiple of the prescribed frequency m whenever the first pulse p1 or the second pulse p2 is applied. For example, the application frequency i of a pulse, the total frequency n, and the prescribed frequency m are recorded in the memory of the control unit 6 and counted by a counter of the control unit 6.

When the application frequency i of a pulse is equal to or greater than the total frequency n, the process flow ends. When the application frequency i of a pulse is not greater than the total frequency n, it is determined whether the application frequency i of a pulse is equal to a multiple of the prescribed frequency m. When the application frequency i of a pulse is not a multiple of the prescribed frequency m, the process flow returns to the process of applying the first pulse p1. When the application frequency i of a pulse reaches a multiple of the prescribed frequency m, the process flow proceeds to the process of applying the second pulse p2.

Subsequently, the pulse application device 3 outputs the second pulse p2 to a plurality of magnetic domain wall movement elements 100 in accordance with the operation program. The second pulse p2 may be applied successively a plurality of times. The second pulse p2 may be applied simultaneously to two or more magnetic domain wall movement elements 100 out of the plurality of magnetic domain wall movement elements 100. By simultaneously applying the second pulse p2 to the plurality of magnetic domain wall movement elements 100, it is possible to decrease the number of magnetic domain wall movement elements 100 in which the magnetic domain wall DW in the integrated area 1 is trapped.

For example, the voltage Vₚ₂ of the second pulse p2 is higher than the voltage Vₚ₁ of the first pulse p1. The voltage values Vₚ₁ and Vₚ₂ are absolute values, and the polarities (plus and minus) thereof may be opposite. The pulse application device 3 applies the second pulse p2 whenever the first pulse p1 is output by the prescribed frequency m. For example, the application frequency of the second pulse p2 is lower than the application frequency of the first pulse p1. The second pulse p2 is a trap escape pulse capable of moving the trapped magnetic domain wall DW.

When the voltage Vₚ₂ of the second pulse p2 is higher than the voltage Vₚ₁ of the first pulse p1, it is preferable that a pulse width tₚ₂ of the second pulse p2 be shorter than a pulse width tₚ₁ of the first pulse p1. The pulse width is half-value amplitude. When products of the pulse voltages and the pulse widths of the first pulse p1 and the second pulse p2 are substantially constant, moving distances of the magnetic domain wall DW at the time of application of the first pulse p1 and at the time of application of the second pulse p2 are substantially equal. When the moving distance of the magnetic domain wall DW is constant, a conductance change of the magnetic domain wall movement element 100 is linear.

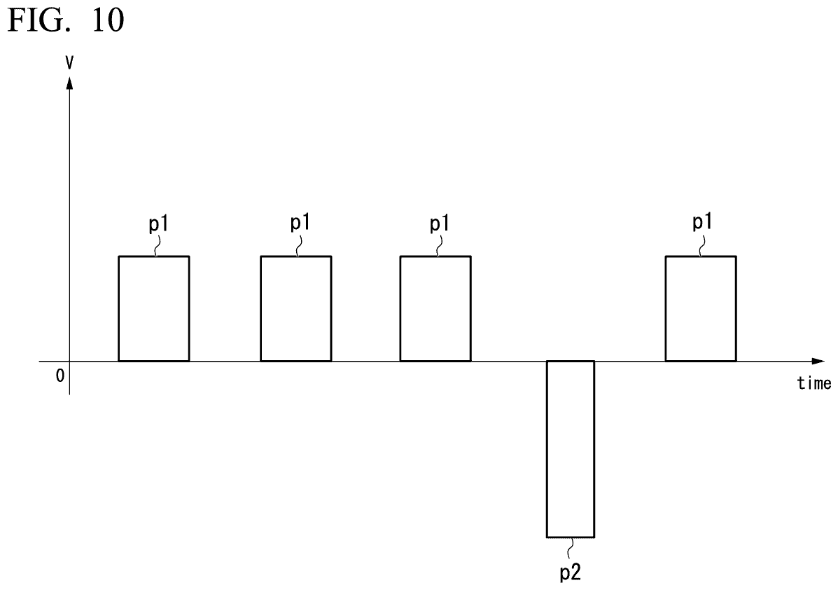

The polarity of the second pulse p2 may be opposite to the polarity of the first pulse p1 which is applied immediately before. FIG. 10 illustrates another example of the temporal change of a pulse which is output by the pulse application device 3. The polarity of a pulse is an application direction of the pulse. The polarity of a pulse is controlled by the pulse application device 3. The pulse application device 3 is configured to change the polarity of a pulse. For example, the polarity of a pulse propagating from the first magnetization fixing layer 40 to the second magnetization fixing layer 50 is defined as “+,” and the polarity of a pulse propagating from the second magnetization fixing layer 50 to the first magnetization fixing layer 40 is defined as “−.”

Trap escape easiness may differ depending on a moving direction of the magnetic domain wall DW. By inverting the polarities of the first pulse p1 applied immediately before and the second pulse p2, the trap escape probability is increased.

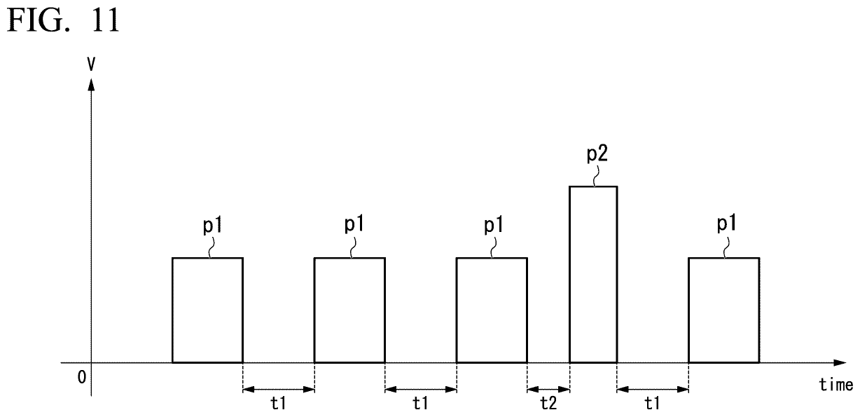

Application intervals of the first pulse p1 and the second pulse p2 may be the same or different. FIG. 11 illustrates another example of the temporal change of a pulse which is output by the pulse application device 3. For example, a pulse interval t2 between the second pulse p2 and the first pulse p1 applied immediately before the second pulse p2 is shorter than a pulse interval t1 between the first pulse p1 applied immediately before the second pulse p2 and the first pulse p1 applied two times before the second pulse p2. By setting the pulse interval t2 at the time of application of the second pulse p2 is shorter than a normal pulse interval t1, the magnetic domain wall movement layer 10 is more likely to emit heat at the time of application of the second pulse p2, and the trap escape probability of the magnetic domain wall DW can be increased using the heat.

The magnetic array MA completes the writing operation by causing a computer to execute the operation program as described above.

The process flow based on the operation program of outputting the second pulse p2 whenever the first pulse p1 is output by the prescribed frequency m has been described above, but the operation program used at the time of writing is not limited thereto.

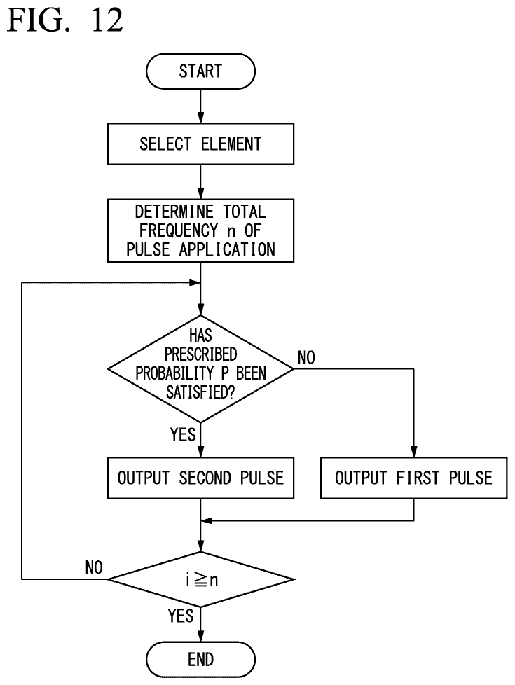

FIG. 12 is a flowchart illustrating another example of an operation program. The operation program includes a process of selecting a magnetic domain wall movement element 100 to which a pulse is to be applied, a process of determining a total frequency n in which a pulse is to be applied, a process of determining whether a prescribed probability P is satisfied, a process of applying a first pulse p1 or a second pulse p2 to a plurality of magnetic domain wall movement elements 100, and a process of determining whether an application frequency i of a pulse is equal to or greater than the total frequency n.

The process of selecting a magnetic domain wall movement element 100 to which a pulse is to be applied and the process of determining the total frequency n by which a pulse is applied are the same as in the operation program illustrated in FIG. 7.

The pulse application device 3 determines whether the first pulse p1 is to be applied or whether the second pulse p2 is to be applied in accordance with the operation program. The pulse application device 3 outputs the second pulse p2 with the prescribed probability P. The first pulse p1 and the second pulse p2 are the same as described above in the operation program illustrated in FIG. 7.

For example, the prescribed probability P is set in advance. The prescribed probability P may be defined for each magnetic domain wall movement element 100, may be defined as the same probability for all the magnetic domain wall movement elements 100, or may be defined for each row or column. For example, the prescribed probability P may be defined for the magnetic domain wall movement elements 100 connected to the same first line WL. The prescribed probability P may be set to, for example, less than 50%, and the application frequency of the second pulse p2 may be set to be lower than the application frequency of the first pulse p1.

The prescribed probability P may change with the elapse of time. For example, when the magnetic array MA is used as a neural network, the prescribed probability P may change according to a progress status of learning of the neural network. For example, when the magnetic array MA is used as a neural network, the prescribed probability P is set to be lower at the time of end of learning than at the time of start of learning of the neural network. That is, the probability with which the second pulse p2 is output is set to be lower at the time of end of learning than at the time of start of learning of the neural network.

Subsequently, the operation program causes a computer to perform the process of determining whether the application frequency i of a pulse is equal to or greater than the total frequency n. The application frequency i of a pulse and the total frequency n are recorded, for example, on the memory of the control unit 6 and counted by the counter of the control unit 6.

When the application frequency i of a pulse is equal to or greater than the total frequency n, the process flow ends. When the application frequency i of a pulse is less than the total frequency n, the process flow returns to the process of applying a pulse.

An operation of reading a signal from the magnetic array MA will be described below. The reading operation is performed, for example, by causing the processor to execute the operation program stored in the control unit 6.

The operation program includes a process of selecting a magnetic domain wall movement element 100 to which a pulse is to be applied and a process of applying a pulse.

First, the pulse application device 3 selects a magnetic domain wall movement element 100 to which a pulse is to be applied in accordance with the operation program. When the magnetic array MA is used as a magnetic memory, the magnetic domain wall movement element 100 to which a reading pulse is to be applied is an element from which data is read. When the magnetic array MA is used as a neural network, application of the reading pulse to a predetermined magnetic domain wall movement element 100 corresponds to a product operation of an input and a weight. That is, when the magnetic array MA is used as a neural network, the reading operation is an operation of identifying the neural network.

To which magnetic domain wall movement element 100 out of a plurality of magnetic domain wall movement elements 100 a pulse is to be applied is controlled by the control unit 6. The control unit 6 turns on the third switching element SW3 and the second switching element SW2 connected to the magnetic domain wall movement element 100 to which a pulse is to be applied and turns off the third switching element SW3 and the second switching element SW2 connected to the other magnetic domain wall movement element 100.

Subsequently, the pulse application device 3 applies the reading pulse to a predetermined magnetic domain wall movement element 100 in accordance with the operation program. The reading pulse is applied, for example, across the ferromagnetic layer 30 and the second magnetization fixing layer 50. The voltage of the reading pulse is a voltage with which a current density less than the threshold current density required for moving the magnetic domain wall DW of the magnetic domain wall movement layer 10 is acquired. That is, the reading pulse does not move the magnetic domain wall DW.

The resistance detection device 4 detects a resistance value of the magnetic domain wall movement element 100 to which the reading pulse has been applied. For example, the output unit 5 outputs the operation result to the outside.

The magnetic array MA according to this embodiment applies the second pulse p2 capable of causing a magnetic domain wall DW to escape from a trap every multiple of the prescribed frequency m or with the prescribed probability P. Accordingly, it is possible to decrease the number of magnetic domain wall movement elements 100 in which the magnetic domain wall DW continues to be trapped and a resistance value does not change. The magnetic domain wall movement element 100 in which the resistance value does not change cannot take charge of storage of data. When there is a magnetic domain wall movement element 100 in which the resistance value does not change, efficiency of learning of a neural network decreases. The magnetic array MA according to this embodiment can apply the second pulse p2 to decrease the number of magnetic domain wall movement elements 100 not operating.

By applying the second pulse p2 every multiple of the prescribed frequency m or with the prescribed probability P, it is possible to cause a trapped magnetic domain wall DW to escape without ascertaining a magnetic domain wall movement element 100 in which the magnetic domain wall DW is trapped even when the magnetic domain walls DW are randomly trapped.

While an exemplary embodiment of the present invention has been described above in detail, the present invention is not limited to the embodiment.

An example in which the voltage Vₚ₂ of the second pulse p2 is higher than the voltage Vₚ₁ of the first pulse p1 has been described above, but the present invention is not limited to this example.

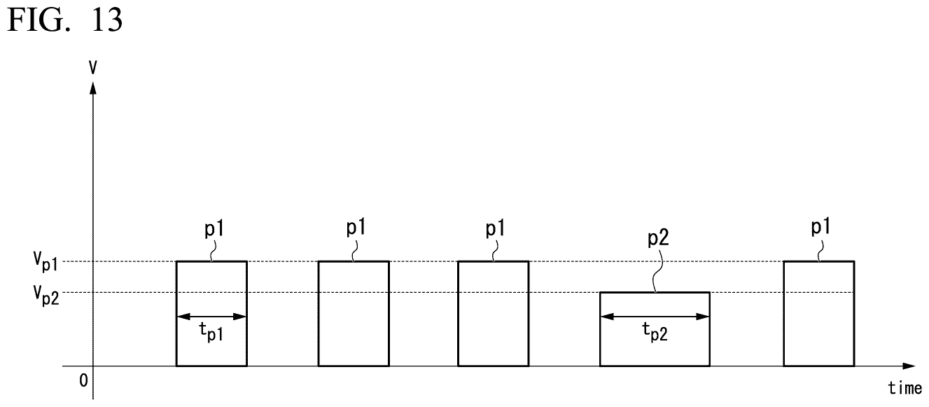

FIG. 13 illustrates an example of a temporal change of a pulse which is output from the pulse application device 3. As illustrated in FIG. 13, the pulse width tₚ₂ of the second pulse p2 may be set to be larger than the pulse width tₚ₁ of the first pulse p1.

When the second pulse p2 has a larger pulse width, it is possible to promote emission of heat from the magnetic domain wall movement layer 10 and to cause a trapped magnetic domain wall DW to escape.

When the pulse width tₚ₂ of the second pulse p2 is larger than the pulse width tₚ₁ of the first pulse p1, it is preferable that the voltage Vₚ₂ of the second pulse p2 be lower than the voltage Vₚ₁ of the first pulse p1. When products of the pulse voltages and the pulse widths of the first pulse p1 and the second pulse p2 are substantially constant, moving distances of the magnetic domain wall DW at the time of application of the first pulse p1 and at the time of application of the second pulse p2 are substantially equal. When the moving distance of the magnetic domain wall DW is constant, a conductance change of the magnetic domain wall movement element 100 is linear.

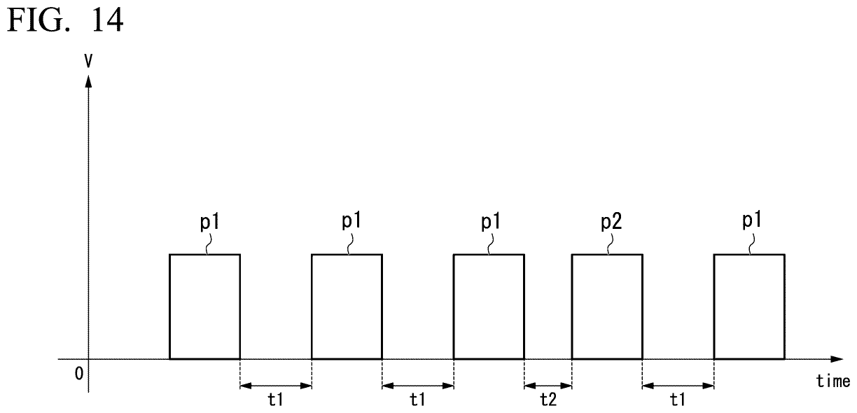

FIG. 14 illustrates an example of a temporal change of a pulse which is output from the pulse application device 3. As illustrated in FIG. 14, the pulse interval t2 at which the second pulse p2 is applied may be set to be shorter than the pulse interval t1 at which the first pulse p1 is applied.

The pulse application device 3 outputs the first pulse p1 at a constant pulse interval t1. The pulse application device 3 may output the first pulse at the constant pulse interval t1 and then output the second pulse p2 at a shorter pulse interval t2 than the constant pulse interval t1.

For example, a pulse interval t2 between the second pulse p2 and the first pulse p1 applied immediately before the second pulse p2 is shorter than a pulse interval t1 between the first pulse p1 applied immediately before the second pulse p2 and the first pulse p1 applied two times before the second pulse p2. By setting the pulse interval t2 at the time of application of the second pulse p2 than a normal pulse interval t1, the magnetic domain wall movement layer 10 is more likely to emit heat at the time of application of the second pulse p2, and the trap escape probability of the magnetic domain wall DW can be increased using the heat.

The magnetic array MA according to this embodiment can be applied as a neuromorphic device.

A neuromorphic device includes, for example, a magnetic array MA and an output converting unit. The output converting unit includes an activation function. The output converting unit is the resistance detection device 4 or the output unit 5. The output converting unit converts a product-sum operation result output from the second line CL on the basis of the activation function.

The neuromorphic device is a device that performs an arithmetic operation of a neural network. The neuromorphic device artificially imitates a relationship between neurons and synapses in the human brain.

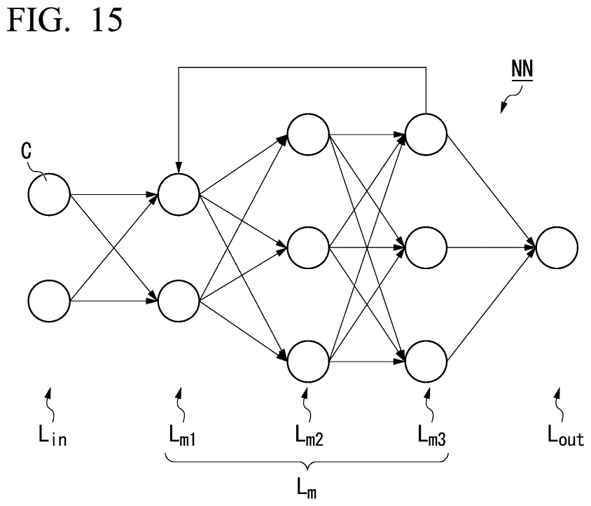

FIG. 15 is a diagram schematically illustrating a neural network NN. The neural network NN includes an input layer Lᵢₙ, an intermediate layer Lₘ, and an output layer Lₒᵤₜ. FIG. 15 illustrates an example in which the number of intermediate layer Lₘ is three, but the number of intermediate layers Lₘ is not particularly limited. Each of the input layer Lᵢₙ, the intermediate layer Lₘ, and the output layer Lₒᵤₜ includes a plurality of chips C, and each chip C corresponds to a neuron in the brain. Each of the input layer Lᵢₙ, the intermediate layer Lₘ, and the output layer Lₒᵤₜ are connected via transmission means. Each transmission means corresponds to a synapse in the brain. The neural network NN trains the transmission means (synapses) to increase a correct answer rate to a problem. Learning is to find knowledge which is likely to be used in the future from information. The neural network NN performs learning by operating while changing weights to be applied to the transmission means. The transmission means performs a product operation of applying a weight to an input signal and a sum operation of summing the product results. That is, the transmission means perform a product-sum operation.

The magnetic array MA can perform a product-sum operation. In the magnetic domain wall movement element 100, the resistance value changes to multiple values or in an analog manner when the position of the magnetic domain wall DW changes. Design of the resistance value of the magnetic domain wall movement element 100 and a conductance value which is a reciprocal thereof corresponds to applying a weight to the transmission means.

For example, in FIG. 2, a current is applied from the third line RL to the second line CL. The current (output value) output from the second line CL varies depending on conductance (weight) of the magnetic domain wall movement element 100. That is, application of a current from the third line RL to the second line CL corresponds to the product operation in the neural network NN. The second line CL is connected to a plurality of magnetic domain wall movement elements 100 in the same column, and the current detected at an end of the second line CL is a value obtained by summing product results in the magnetic domain wall movement elements 100. Accordingly, the magnetic array MA serves as a product-sum operator of the neuromorphic device.

While embodiments of the present invention have been described above in detail, the present invention Is not limited to the embodiments. For example, featured configurations of the embodiments may be combined or may be partially changed without departing from the gist of the present invention.

### REFERENCE SIGNS LIST

1 Integrated area
2 Peripheral area
3 Pulse application device
4 Resistance detection device
5 Output unit
6 Control unit
7 Power supply
10 Magnetic domain wall movement layer
20 Nonmagnetic layer
30 Ferromagnetic layer
40 First magnetization fixing layer
50 Second magnetization fixing layer
90 Insulating layer
100, 101 Magnetic domain wall movement element
WL First line
CL Second line
RL Third line
DW Magnetic domain wall
i Application frequency
m Prescribed frequency
n Total frequency
MA Magnetic array
p1 First pulse
p2 Second pulse
t1, t2 Pulse interval

1. A magnetic array comprising:
a plurality of magnetoresistance effect elements; and
a pulse application device configured to apply a pulse to at least one of the plurality of magnetoresistance effect elements,
wherein each of the plurality of magnetoresistance effect elements includes a magnetic domain wall movement layer, a ferromagnetic layer, and a nonmagnetic layer interposed between the magnetic domain wall movement layer and the ferromagnetic layer,
wherein the pulse application device outputs a first pulse and a second pulse at different times,
wherein voltages of both the first pulse and the second pulse are voltages at which a current density equal to or higher than a threshold current density required for moving a magnetic domain wall of the magnetic domain wall movement layer is acquired,
wherein the second pulse has a higher voltage than the first pulse or a longer pulse length than the first pulse, and
wherein the pulse application device outputs the second pulse whenever the first pulse is output at a prescribed frequency or with a prescribed probability.

2. The magnetic array according to claim 1, wherein a pulse width of the second pulse is smaller than the pulse width of the first pulse when the voltage of the second pulse is larger than the voltage of the first pulse, and the voltage of the second pulse is smaller than the voltage of the first pulse when the pulse width of the second pulse is larger than the pulse width of the first pulse.

3. The magnetic array according to claim 1, wherein an application frequency of the second pulse is lower than the application frequency of the first pulse.

4. The magnetic array according to claim 1, wherein the plurality of magnetoresistance effect elements are arranged in a matrix shape, and
wherein the pulse application device defines the prescribed frequency or the prescribed probability for each row or each column.

5. The magnetic array according to claim 1, wherein the polarity of the second pulse is opposite to the polarity of the first pulse applied immediately before.

6. The magnetic array according to claim 1, wherein the pulse application device simultaneously applies the second pulse to two or more magnetoresistance effect elements out of the plurality of magnetoresistance effect elements.

7. The magnetic array according to claim 1, wherein the pulse application device successively outputs the second pulse a plurality of times.

8. The magnetic array according to claim 1, wherein a pulse interval between the second pulse and the first pulse applied immediately before the second pulse is shorter than a pulse interval between the first pulse applied immediately before the second pulse and the first pulse applied two times before the second pulse.

9. The magnetic array according to claim 1, wherein the magnetic array is used for a neural network, and
wherein the pulse application device updates the prescribed frequency or the prescribed probability according to a progress status of learning of the neural network.

10. The magnetic array according to claim 9, wherein the pulse application device sets the prescribed frequency to be larger or sets the prescribed probability to be smaller at the time of end of learning of the neural network than at the time of start of learning thereof.

11. A magnetic array comprising:
a plurality of magnetoresistance effect elements; and
a pulse application device configured to apply a pulse to at least one of the plurality of magnetoresistance effect elements,
wherein each of the plurality of magnetoresistance effect elements includes a magnetic domain wall movement layer, a ferromagnetic layer, and a nonmagnetic layer interposed between the magnetic domain wall movement layer and the ferromagnetic layer,
wherein the pulse application device outputs a first pulse at a constant pulse interval and then outputs a second pulse at a pulse interval shorter than the constant pulse interval,
wherein the pulse application device outputs the second pulse whenever the first pulse is output at a prescribed frequency or with a prescribed probability, and
wherein voltages of both the first pulse and the second pulse are voltages at which a current density equal to or higher than a threshold current density required for moving a magnetic domain wall of the magnetic domain wall movement layer is acquired.

12. A magnetic array comprising:
a plurality of magnetoresistance effect elements; and
a pulse application device configured to apply a pulse to at least one of the plurality of magnetoresistance effect elements,
wherein each of the plurality of magnetoresistance effect elements includes a magnetic domain wall movement layer, a ferromagnetic layer, and a nonmagnetic layer interposed between the magnetic domain wall movement layer and the ferromagnetic layer,
wherein the pulse application device outputs a learning pulse and a trap-escape pulse at different times,
wherein voltages of both the learning pulse and the trap-escape pulse are voltages at which a current density equal to or higher than a threshold current density required for moving a magnetic domain wall of the magnetic domain wall movement layer is acquired, and
wherein the voltage of the trap-escape pulse is larger than the voltage of the learning pulse or a pulse length of the trap-escape pulse is larger than the pulse length of the learning pulse.

13. An operation method for a magnetic array, comprising:
a step of applying a first pulse to a plurality of magnetoresistance effect elements; and
a step of applying a second pulse to the plurality of magnetoresistance effect elements whenever the first pulse is applied at a prescribed frequency or with a prescribed probability,
wherein each of the plurality of magnetoresistance effect elements includes a magnetic domain wall movement layer, a ferromagnetic layer, and a nonmagnetic layer interposed between the magnetic domain wall movement layer and the ferromagnetic layer,
wherein voltages of both the first pulse and the second pulse are voltages at which a current density equal to or higher than a threshold current density required for moving a magnetic domain wall of the magnetic domain wall movement layer is acquired, and
wherein the second pulse has a higher voltage than the first pulse or a longer pulse length than the first pulse.

14. The operation method for a magnetic array according to claim 13, wherein a pulse width of the second pulse is smaller than the pulse width of the first pulse when the voltage of the second pulse is larger than the voltage of the first pulse, and the voltage of the second pulse is smaller than the voltage of the first pulse when the pulse width of the second pulse is larger than the pulse width of the first pulse.

15. The operation method for a magnetic array according to claim 13, wherein an application frequency of the second pulse is lower than the application frequency of the first pulse.

16. The operation method for a magnetic array according to claim 13, wherein the step of applying the second pulse includes simultaneously applying the second pulse to two or more magnetoresistance effect elements out of the plurality of magnetoresistance effect elements.

17. The operation method for a magnetic array according to claim 13, wherein a pulse interval between the second pulse and the first pulse applied immediately before the second pulse is shorter than a pulse interval between the first pulse applied immediately before the second pulse and the first pulse applied two times before the second pulse.

18. An operation method for a magnetic array, comprising:
a step of applying a first pulse to a plurality of magnetoresistance effect elements; and
a step of applying a second pulse to the plurality of magnetoresistance effect elements whenever the first pulse is applied at a prescribed frequency or with a prescribed probability,
wherein each of the plurality of magnetoresistance effect elements includes a magnetic domain wall movement layer, a ferromagnetic layer, and a nonmagnetic layer interposed between the magnetic domain wall movement layer and the ferromagnetic layer,
wherein the first pulse is applied at a constant pulse interval, and the second pulse is applied at a pulse interval shorter than the constant pulse interval, and
wherein voltages of both the first pulse and the second pulse are voltages at which a current density equal to or higher than a threshold current density required for moving a magnetic domain wall of the magnetic domain wall movement layer is acquired.

19. (canceled)

20. (canceled)

21. (canceled)

22. (canceled)

23. (canceled)

24. (canceled)
